(19) United States
(12) Patent Application Publication
(10) Pub. No.: US 2017/0202114 A1
(43) Pub. Date: Jul. 13, 2017

(54) IMPROVED RAIL COOLING ARRANGEMENT FOR SERVER APPARATUS

(71) Applicant: ADC TECHNOLOGIES INC., Montreal (CA)

(72) Inventor: Niall Thomas DAVIDSON, Hamilton (GB)

(21) Appl. No.: 15/324,477

(22) PCT Filed: Jul. 8, 2015
(86) PCT No.: PCT/CA2015/050634

§ 371 Date: Jan. 6, 2017

Related U.S. Application Data
(60) Provisional application No. 62/022,015, filed on Jul. 8, 2014.
(60) Provisional application No. 62/022,032, filed on Jul. 8, 2014.
(60) Provisional application No. 62/022,044, filed on Jul. 8, 2014.
(60) Provisional application No. 62/022,056, filed on Jul. 8, 2014.

(51) Int. Cl. H05K 7/20

(52) U.S. Cl. CPC H05K 7/20809; H05K 7/20336

(57) ABSTRACT

Described are computer server apparatus of a type which are cooled by installation into a cooled enclosure in a data enter, the cooled enclosure of a type characterized by having a plurality of channels which are configured to cool installed apparatus by contacting a thermally conductive surface on a rail of the installed apparatus. Disclosed are chassis and arrangements of thermal components which provide short thermal paths between heat generating components and the cooled enclosure. Also described is a slide assembly which enables computer system apparatus to be easily installed and removed from a cooled enclosure. The slide assembly configured to be installed on a rail portion of the computer system and comprises a retractable support in the form of a retractable wheel which is configured to support the computer chassis during installation into the cooled enclosure.

### CROSS-REFERENCE TO RELATED APPLICATIONS

The present application claims the benefits of priority of U.S. Provisional Patent Application No. 62/022,015, entitled “Computer System with Improved Thermal Rail” filed at the United States Trademark and Patent Office (“USPTO”) on Jul. 8, 2014, which content is incorporated herein by reference in its entirety. The present application also claims the benefits of priority of U.S. Provisional Patent Applications Nos. 62/022,044, 62/022,056, 62/022,032 respectively entitled “Robust Redundant-Capable Leak-Resistant Cooled Enclosure Wall”, “Slide Assembly for Thermal Rail Cooled Systems” and “Efficiently Cooling Data Centers using Thermal Rail Technology” filed at the USPTO on Jul. 8, 2014 which are incorporated herein by reference in their entirety.

### BACKGROUND

Data centers are a prominent feature of modem life and the cooling of computer systems such as computer servers and network apparatus are a central part of a data centers operation.

Previous work by this inventor disclosed in patent application published under no. WO/2014/030046 describes computer system apparatus which in cooperation with a cooled enclosure can remove heat efficiently and cost effectively. FIG. 1 illustrates an example of a computer system apparatus embodying features described previously by this inventor.

Improvements in any technology is desirable and the present disclosure is directed to an improvement for computer system apparatus which can be cooled by its installation within a cooled enclosure in a data center environment.

### SUMMARY

The present disclosure is directed to a computer system which can be cooled by installation into a cooled enclosure of the type described in WO/2014/030046 and the patent application entitled “Robust Redundant-Capable Leak-Resistant Cooled Enclosure Wall”.

Benefits which may be enjoyed by apparatus embodying features of the present disclosure include, but are not limited to, a short thermal path between heat generating components and the cooled surface of a cooled enclosure thus enabling reduced thermal resistance and improving cooling efficiency. Further benefits of apparatus embodying features of the present disclosure may also include reduced manufacturing and assembly complexity and therefore reduced manufacturing costs.

One exemplary computer system described comprises a heat generating component, a heat transmitting device and a chassis with an integrated rail portion, the rail portion being configured such that when the chassis is installed within the enclosure both the rail portion and a portion of the heat transmitting device are contained within the channel of the enclosure. The rail portion is further configured with an aperture that allows a portion of the heat transmitting device contained within the channel of the enclosure to be brought into contact with the cooled surface of the enclosure when the computer system is installed within the cooled enclosure, thus creating a short and direct thermal path between the heat transmitting device and the cooled surface of the cooled enclosure.

Another exemplary computer system described comprises a heat generating component, a heat transmitting device and a chassis with an integrated rail portion, the rail portion being configured such that when the chassis is installed within the enclosure both the rail portion and a portion of the heat transmitting device are contained within the channel of the enclosure. A portion of the heat transmitting device contained within the channel of the enclosure is then thermally connected to the rail portion and thus when the computer system is installed within a cooled enclosure a short thermal path between the heat transmitting device and the cooled surface of the cooled enclosure is created via the rail.

Another exemplary computer system described comprises a heat generating component, a heat transmitting device and a chassis with an integrated rail portion further combined with a heat spreader, the rail portion being configured such that when the chassis is installed within the enclosure both the rail portion and a portion of the heat transmitting device are contained within the channel of the enclosure. A portion of the heat transmitting device contained within the channel of the enclosure is then thermally connected to the rail portion, thus when the computer system is installed within a cooled enclosure a short thermal path between the heat transmitting device and the cooled surface of the cooled enclosure is created via the rail portion. The heat spreader further improving cooling efficiency by spreading the heat efficiently over a greater length of the rail portion.

Computer system apparatus having a rail portion may be installed by sliding the apparatus into a compatible cooled enclosure. Whilst this can be achieved with no mechanical assistance, ensuring that the apparatus is installed without damaging attached thermal interface materials such as gap pads may be difficult to achieve.

Also disclosed is a slide assembly for computer system apparatus which can be cooled by installation within a cooled enclosure in a data center environment. The slide assembly enabling computer system apparatus to be installed and removed from cooled enclosures without causing damage to attached thermal interface materials and reducing installation difficulty.

A described slide assembly is configured to be combined with a computer chassis comprising a rail portion, the rail portion configured to be received by a channel within a cooled enclosure. The slide assembly comprises a retractable support, in the form of a retractable wheel, which is configured to support the computer chassis during installation into the cooled enclosure and can be retracted once the computer chassis is in its installed position.

The described slide assembly is further configured to combine with the computer system chassis in such a way that the slide assembly can be quickly, and without tools, removed from it's operating position to permit access to components installed on the rail portion of the chassis. This yields the benefit that the addition of the slide assembly does not negatively impact the complexity of computer system maintenance or significantly increase the time to perform that maintenance.

### BRIEF DESCRIPTION OF THE DRAWINGS

These and other features, aspects, and advantages of the present invention will become better understood with regard to the following description, appended claims, and accompanying drawings where:

FIG. 1 shows a perspective view of a computer system previously disclosed by the present inventor;

FIG. 2 shows a partial view of the interaction between a rail of the prior art computer system shown in FIG. 1 and the channel of a cooled enclosure when the computer system is installed in the enclosure;

FIG. 3 shows a perspective view of a chassis suitable for use in a computer system;

FIG. 4a shows a partially exploded view of a heatpipe assembly suitable for use with a computer system comprising the chassis of FIG. 3;

FIG. 4b shows the same view as FIG. 4a without explosion;

FIG. 5 shows a partially exploded computer system comprising the chassis of FIG. 3 and heatpipe assemblies including that illustrated in FIGS. 4a and 4b;

FIG. 6 shows the computer system of FIG. 5 in a partially installed position in a cooled enclosure;

FIG. 7 shows a partial front view of a rail of the computer system of FIG. 5 when installed in a cooled enclosure as shown in FIG. 6;

FIG. 8 shows a perspective view of an alternative chassis suitable for use in a computer system;

FIG. 9a, b and c illustrates fastening features integrated into the chassis of FIG. 8;

FIG. 10 shows a shows a partially exploded computer system comprising the chassis of FIGS. 8 and 9;

FIG. 11 shows the computer system of FIG. 10 in a partially installed position in a cooled enclosure;

FIG. 12 shows a partial front view of a rail of the computer system of FIG. 10 when installed in a cooled enclosure as shown in FIG. 11;

FIG. 13 shows an exploded view of an alternative configuration of the chassis of FIG. 8;

FIG. 14a shows an isometric view of an exploded slide assembly;

FIG. 14b shows an exploded view of a wheel assembly from the slide assembly of FIG. 14a;

FIG. 14c shows the assembled wheel assembly of FIG. 14b;

FIG. 14d shows a partial top view of the body of the slide assembly of FIG. 14a showing the configuration of an opening configured to receive the wheel assembly of FIGS. 14b and 14c;

FIG. 14e shows a partial perspective view of the slide assembly of FIG. 14a illustrating a wheel assembly protruding through a surface of the body of the slide assembly of FIG. 14a;

FIG. 14f shows a partial exploded view of the slide assembly of FIG. 14a illustrating features which limit the movement of the force transfer rod;

FIGS. 15a, 15b and 15c illustrate the interaction between the inclined plane features of the force transfer rod and wheel assemblies of the slide assembly of FIG. 14a;

FIG. 16a shows a computer server with a slide assembly, of the type shown in FIG. 14a, installed on each rail portion of the chassis;

FIG. 16b provides a close up view of the computer server of FIG. 16a and illustrates chassis features which engage with axles of the body of each slide assembly;

FIG. 16c provides a close up view of the computer server of FIG. 16a and illustrates chassis features which engage with snap-fit hooks of the body of each slide assembly;

FIG. 16d shows a view of the computer server of FIG. 16a with each slide assembly in its operating position, and;

FIG. 16e provides a close up view of the computer server of FIG. 16d and illustrates a lever part which can be used to deploy the wheels of the slide assembly.

### DETAILED DESCRIPTION

It is intended that the following description and claims should be interpreted in accordance with Webster's Third New International Dictionary, Unabridged unless otherwise indicated.

In the following specification and claims, a “heat transmitting means” or “heat transmitting device” is intended to encompass heatpipes, vapor chambers, thermosyphons, thermal interface materials and thermally conductive materials, composites, manufactures and apparatus such as: thermally conductive metals, examples of which include copper, aluminium, beryllium, silver, gold, nickel and alloys thereof; thermally conductive non-metallic materials, examples of which include diamond, carbon fiber, carbon nanotubes, graphene, graphite and combinations thereof; composite materials and manufactures, examples of which include graphite fiber/copper matrix composites and encapsulated graphite systems; thermally conductive filled plastics, examples of which include metal filled plastics, graphite filled plastics, carbon nanotube filled plastics, graphene filled plastics and carbon fiber filled plastics; and apparatuses such as liquid circulation, heat pumps and heat exchangers. A “heat transmitting means” or “heat transmitting device” is further intended to encompass any means presently existing or that is discovered in the future which transmits heat from one place to another.

In the following specification and claims the term “contained within the channel” is defined to be interpreted to mean that something is “contained within the channel” if that something lies within the space enclosed by: the imaginary surface of minimum surface area that joins the external edges of the channel, and; the surfaces of the channel.

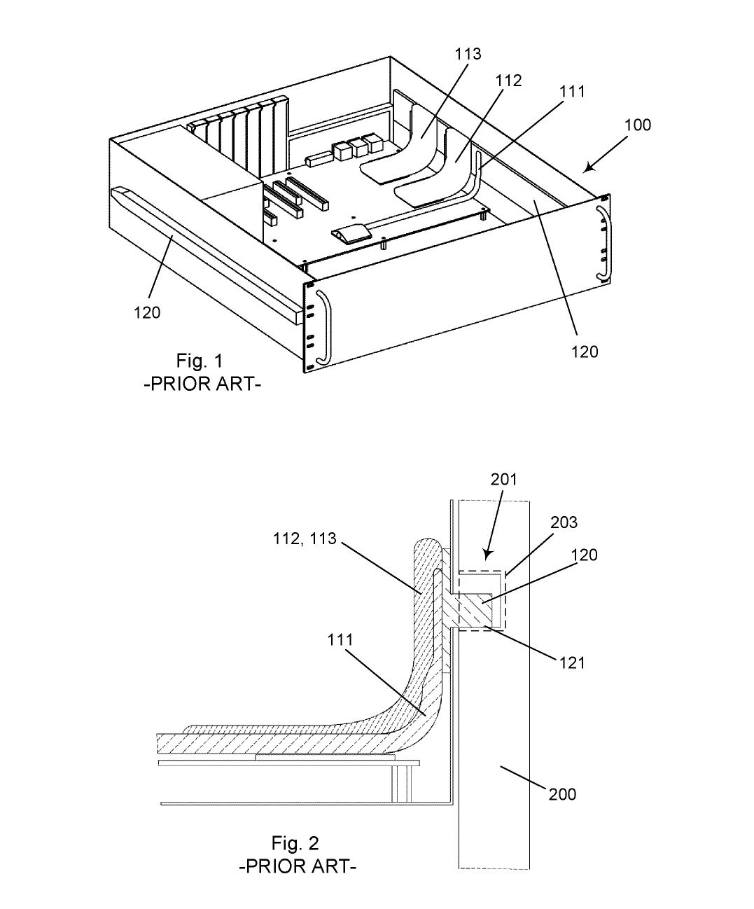

Previous work by this inventor disclosed in patent application published under no. WO/2014/030046 describes a computer system having a rail configured to be received by a channel in a compatible enclosure. The computer system 100 shown in FIG. 1 illustrates the computer system described previously, shown are two rails 120 and a number of heat transmitting devices in the form of heatpipes 111, 112 and 113.

FIG. 2 shows a partial view from the front of computer system 100 installed in a cooled enclosure 200 and illustrates the interaction between rail 120 and a channel 201 of the enclosure 200. The heatpipes 111, 112 and 113 are shown to be in thermal contact with a rail 120 in a plane perpendicular to the thermally conductive surface 121 of the rail 120. This configuration results in a long thermal path between the heat transmitting devices 111, 112 and 113 and the surface 121. Further, because of the way contact is made between the rail 120 and heat transmitting devices 111, 112 and 113 the minimum height of the computer system 100 is increased and a 90 degree bend is introduced into the heatpipes 111, 112 and 113. As heatpipe efficiencies are decreased by such bending it is desirable to avoid them when possible.

Referring again to FIG. 2 it can be seen that no portion of the heat transmitting devices 111, 112 and 113 will be contained within the channel 201 of the enclosure 200 when the computer system 100 is installed within the enclosure 200. This is illustrated by the dashed line 203 which outlines channel 201 and it can be seen that no portion of heat transmitting devices 111, 112 or 113 cross the dashed line 203 into the channel 201.

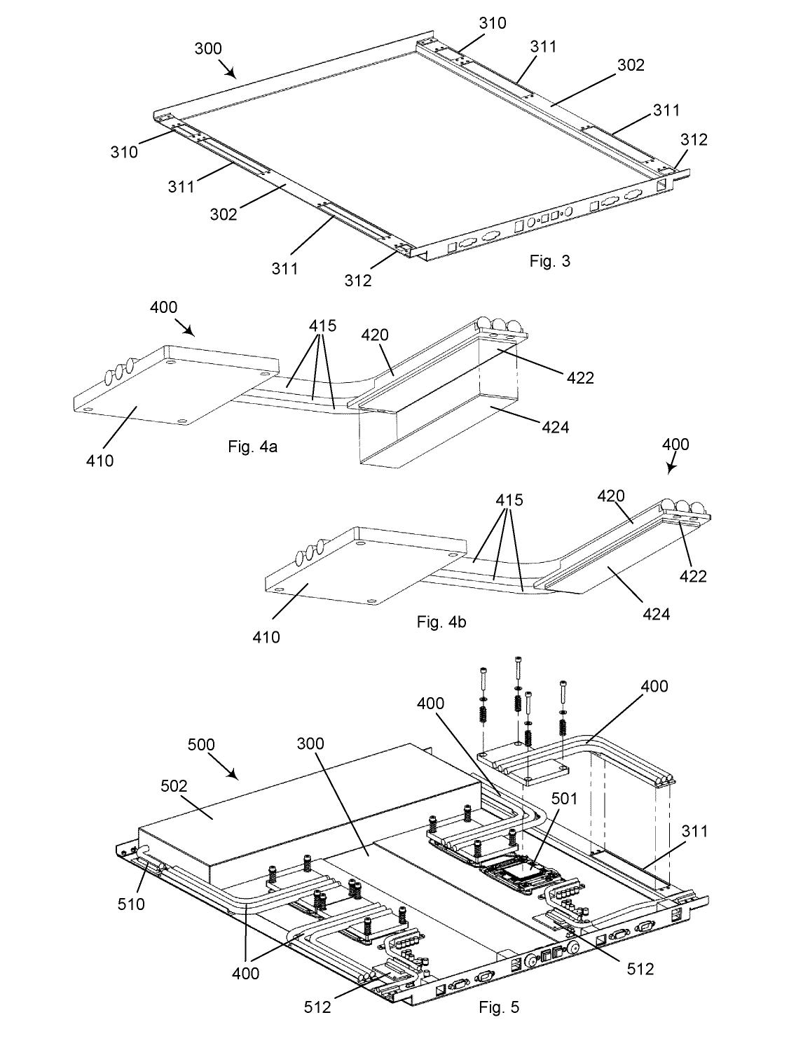

FIG. 3 illustrates a chassis 300 of a computer system embodying features of the present disclosure, the computer system suited for use in the data center. The chassis 300 features integrated rail portions 302 on opposing sides of the chassis 300, the rail portions 302 being adapted to be received by channels in a cooled enclosure when the computer system is installed in the enclosure. Examples of suitable enclosures, are described in publication no. WO/2014/030046 and the co-pending patent application entitled “Robust Redundant-Capable Leak-Resistant Cooled Enclosure Wall”. However, it shall be understood that any other types of suitable enclosures may be used.

The integrated rail portions 302 of the chassis 300 are further configured with a plurality of apertures 310, 311 and 312 along the length of the rail portions 302, these apertures 310, 311 and 312 are positioned such that when the computer system is installed in the enclosure the apertures 310, 311 and 312 provide access to the cooling surface of the enclosure for heat generating components, further detail regarding the apertures 310, 311 and 312 can be found below.

The chassis 300 can be fabricated from sheet metal and stiffening features such as cross breaks, ribs or additional bracing may be added to decrease deformation when supported only by the rail features 302. The design of the chassis 300 is such that the chassis 300 itself does not take part in the thermal circuit between heat generating components and the cooling surface of the enclosure, as such the chassis 300 need only provide structural support and can thus be fabricated from any material, including plastics, which can provide the necessary support.

FIGS. 4a and 4b show an example of a heatpipe assembly 400, a heat transmitting device, configured for use with the chassis 300 of FIG. 3. The heatpipe assembly 400 is comprised of CPU plate 410, heatpipes 415 and rail plate 420. The CPU plate 410 is configured to be brought into contact with a CPU installed in a motherboard and is thermally connected via heatpipes 415 to the rail plate 420.

Rail plate 420 is configured to be fastened to the rail portion 302 of chassis 300 with at least a portion of rail plate 420 being coincident with an aperture 311, this can be achieved by the use of a temporary fastener such as screws or a more permanent fastening solution such as an adhesive or by welding, brazing or soldering. A projection 422 on rail plate 420 is configured to project through the aperture 311 when installed and a gap pad 424 or similar thermal interface material is affixed to the projection 422. The combination of rail plate 420, projection 422 and gap pad 424 being such that the surface of the gap pad 424 projects beyond the surface of the rail portion 302 of the chassis 300 such that when installed in the cooled enclosure the gap pad 424 is brought into contact with the cooling surface of the enclosure. Thus creating a short thermal path between the enclosure and the CPU, which is a heat generating component, via the gap pad 424, rail plate 420, heatpipes 415 and CPU plate 410.

The gap pad 424 or projection 422 may be omitted from the heatpipe assembly if thermal conditions permit, however the use of a gap pad may reduce manufacturing requirements by enabling parts to be fabricated to a lower tolerance or with less materials; the gap pad absorbing minor imperfections in the plane of contact between the heatpipe assembly and the cooling surface of the enclosure.

Suitable gap pads have been found to include compliant gap pads, for example a boron nitride filled silicone elastomer with manufacturer reported hardness of 70 Shore 00 and thermal conductivity of 6 W/mK, model Tpli-240 produced by Laird Technologies of Schaumburg, Ill. and a gap pad with manufacturer reported hardness of 30 Shore 00 and thermal conductivity of 3 W/mK, model 3000S30 produced by The Bergquist Company of Chanhassen, Minn. were both found to be adequate for a computer system with chassis similar to chassis 300 relying only on the weight of the computer system to provide sufficient thermal contact between the computer system and a cooled surface.

Similar compliant gap pads, including graphite pads and other elastomers are expected to also be suited to this task. If installation is permanent then gap pads with inherent tack may be used, however if regular maintenance is expected a gap pad that is tack free on the surface contacting the cooled enclosure may be beneficial as this may allow the computer system to be removed without damaging the gap pad component. When multiple gap pads are used, as with the computer system described below, attention should be paid to the weight distribution of the computer system, for example a gap pad that has no weight being transferred through it may not make adequate contact with the cooled surface and may indicate that a redesign of the computer system is required to distribute the weight adequately through each pad or that a means for urging the gap pad against the surface of the cooled enclosure is required.

FIG. 5 shows a computer system 500 comprising the chassis 300 and a plurality of heatpipe assemblies 400 corresponding to one of four installed CPUs 501. FIG. 5 is also partially exploded illustrating the alignment between one of the heatpipe assemblies 400 and an aperture 311 of the chassis 300. The computer system 500 further comprises additional heat generating components which are cooled in a similar fashion to the CPUs by using similar heat transmitting means configured appropriately for their different heat dissipation requirements. The PSU 502 having a heatpipe assembly 510 corresponding to apertures 310 and chipset and VRM components having heatpipe assemblies 512 corresponding to aperture 312. Cooling is not limited to those components described here and by following the examples and teachings disclosed any heat generating component can be cooled in a similar fashion, furthermore the heat transmitting device can take any form and is not required to be of the type shown.

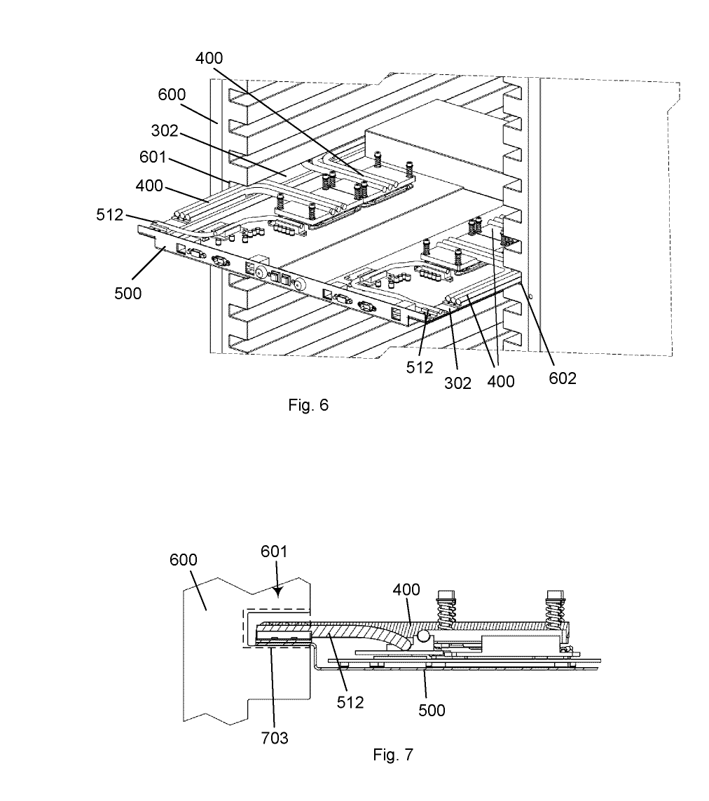

FIG. 6 shows the computer system 500 of FIG. 5 partially installed into a cooled enclosure 600, as can be seen the rail portions 302 of the chassis 300 are supported by channels 601 and 602 in the enclosure with portions of the heat transmitting devices 400 and consequently at least a portion of apertures 311 (not visible in FIG. 6) being contained within the channel 601 and 602 of the enclosure when installed. This can be seen further by referring to FIG. 7 which shows a partial view of the interaction of a rail portion 302 of the computer system 500 and enclosure 600 when the computer system 500 is installed in the enclosure 600. Referring to the dashed line 703 of FIG. 7 which outlines channel 601, it can be seen that a portion of a heat transmitting device 400 as well as a portion of heat transmitting device 512 cross the dashed line 703 into the channel 601, thus the heat transmitting device 400 and 512 are both contained within the channel 601.

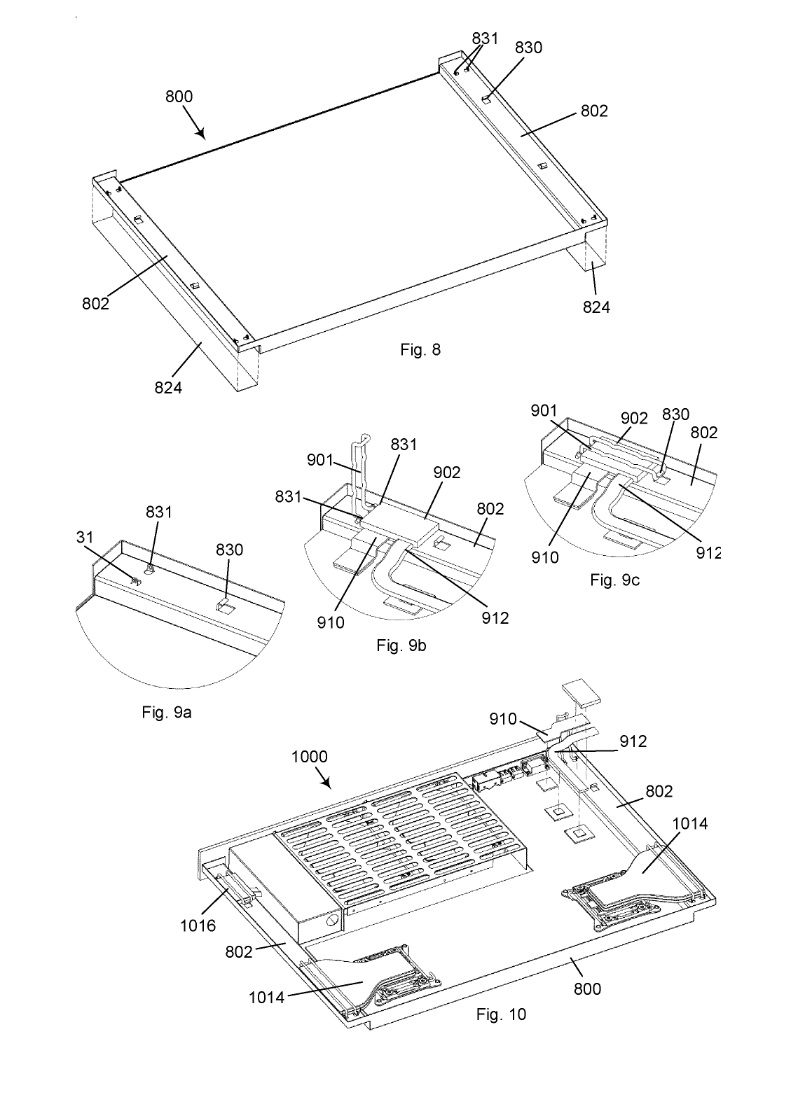

Now referring to FIG. 8 which shows an alternative chassis 800 for a computer system embodying features of the present disclosure, the computer system suited for use in the data center. The chassis 800 features integrated rail portions 802 on opposing sides of the chassis 800, the rail portions 802 being adapted to be received by channels in a cooled enclosure when the computer system is installed in the enclosure. Suitable enclosures are described in WO/2014/030046 and the co-pending patent application titled “Robust Redundant-Capable Leak-Resistant Cooled Enclosure Wall”.

Chassis 800 provides structural support for components installed within it and the rail portion 802 also forms a part of the thermal circuit made between installed heat generating components and the cooling surface of a cooled enclosure. As such the rail portion 802 is made from a thermally conductive material that can perform both functions, depending on thermal needs this could be aluminum, steel or another thermally conductive metal however it could also be fabricated from another thermally conductive material such as a thermally conductive filled plastic. The chassis 800 may be made from a single piece of sheet metal if desired and stiffening features such as cross breaks, ribs or additional bracing may be added to decrease deformation when supported only by the rail portion 802.

The chassis 800 may further comprise gap pads 824 or other thermal interface materials which are affixed to the rail portions 802 and positioned to provide thermal contact between the cooling surface of a cooled enclosure and chassis 800 when the computer system is installed into the enclosure. Depending on thermal requirements the gap pads 824 may not be required for the full length of the rail portion 802 minimizing the use of redundant material. Gap pads 824 may also be omitted if thermal conditions permit, however the use of a gap pad can reduce manufacturing requirements by enabling parts to be fabricated to a lower tolerance or with less materials; the gap pad absorbing minor imperfections in the plane of contact between the chassis 800 and the cooling surface of the enclosure. Suitable gap pads have been described previously.

The chassis 800 may further comprise features for quick and tool-less fastening of heat transmitting devices to the chassis 800, these features include eyelets 831 and catch 830. These features can be integrated into the chassis 800 during manufacturing and provide an example of how components can be urged against the rail portions 802 in a quick and easy tool-less fashion.

Now referring to FIGS. 9a, 9b and 9c, the use of the eyelets 831 and catch 830 to urge components against the rail portion 802 of the chassis 800 is illustrated. FIG. 9a shows a close up view of eyelets 831 and catch 830 whilst FIG. 9b shows components 910 and 912 in position and ready to be urged against rail portion 802 of the chassis 800, components 910 and 912 are described further below. In addition FIG. 9b shows a wire spring 901 in an unlocked position with its legs shown inserted into eyelets 831, also shown is force transfer component 902 which transfers force from the wire spring 901 to the components 910 and 912 when the wire spring 901 is brought into a locked position. FIG. 9c shows the wire spring 901 in a locked position with the end opposite the legs which are inserted into eyelets 831 being hooked into and held by the catch 830, in the locked position force is transferred through the force transfer component 902 into components 910 and 912 whereupon they are urged against the rail portion 802 of the chassis 800.

Now referring to FIG. 10, a partially exploded computer system 1000 comprising the chassis 800 is shown. The system 1000 also comprises a number of heat transmitting means such as thermally conductive material 910, heatpipe 912, vapor chamber 1014 and heatpipe assembly 1016. Each of which is thermally connected to the rail portion 802 of the chassis 800 and a heat generating component via a tool-less fastening solution similar to that described above and integrated into the chassis 800. Other temporary fasteners or a more permanent fastener such as an adhesive or welding, brazing or soldering may also be used if desired. When using a temporary fastener a thermal grease or other thermal interface material may improve thermal conductivity when introduced between the heat transmitting means and rail portion 802.

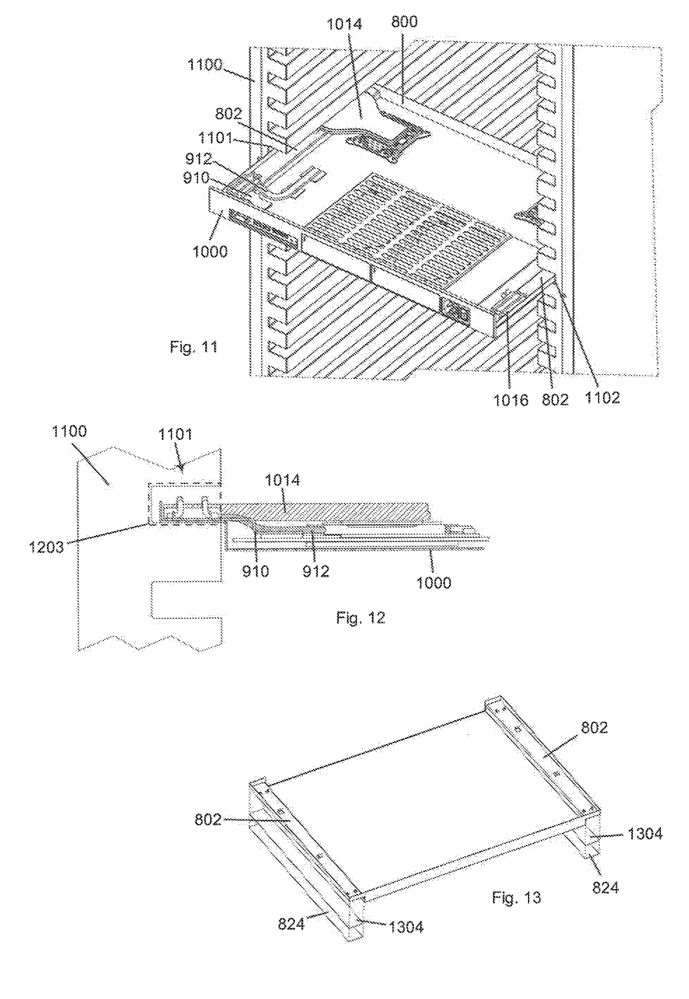

Now referring to FIG. 11, the computer system 1000 of FIG. 10 is shown being partially installed in a cooled enclosure 1100. In such an embodiment the rail portions 802 of the chassis 800 are supported by channels 1101 and 1102 in the enclosure with portions of the heat transmitting devices 910, 912, 1014 and 1016 being contained within a channel 1101 or 1102 of the enclosure when installed. This can be seen further by referring to FIG. 12 which shows a partial front view of the interaction of a rail portion 802 of the computer system 1000 and enclosure 1100 when the computer system 1000 is installed in the enclosure 1100. Referring to the dashed line 1203 of FIG. 12 which outlines channel 1101, it can be seen that portions of heat transmitting devices 910, 912 and 1014 cross the dashed line 1203 into the channel 1101, thus the heat transmitting devices 910, 912 and 1014 are all contained within the channel 1101.

Now referring to FIG. 13, a further embodiment of a configuration of chassis 800, in addition to the optional gap pads 824 a heat spreader 1304 is affixed to rail portion 802. The heat spreader being either: made of a material with a higher conductivity in the xy-axis than the material that the rail portion 802 is fabricated of, for example copper or graphite, or; one or more heatpipes running some or all of the length of the rail portion 802. Such a configuration of chassis 800 with heat spreader 824 may provide greater cooling efficiency by more effectively dissipating heat along a longer length of the surface of a cooled enclosure.

The described apparatus aim at providing several benefits, including but not limited to: a shortened thermal path between the heat transmitting device and the cooled surface of the enclosure thus yielding lower operating temperatures for heat generating components; the potential to simplify manufacturing by enabling the chassis to be manufactured as a single component if desired; a potential reduction in minimum chassis height and thus increased density potential when deployed in a data center environment, and; the potential to simplify the design of heat transmitting devices such as heatpipes and vapor chambers.

Computer system apparatus having a rail portion similar to those described in patent cooperation treaty application published under no. WO 2014/030046 A1 or similar to those described above can be installed by sliding the apparatus into a compatible cooled enclosure. Whilst this can be achieved with no mechanical assistance, ensuring that the apparatus is installed without damaging attached thermal interface materials such as gap pads may be difficult to achieve.

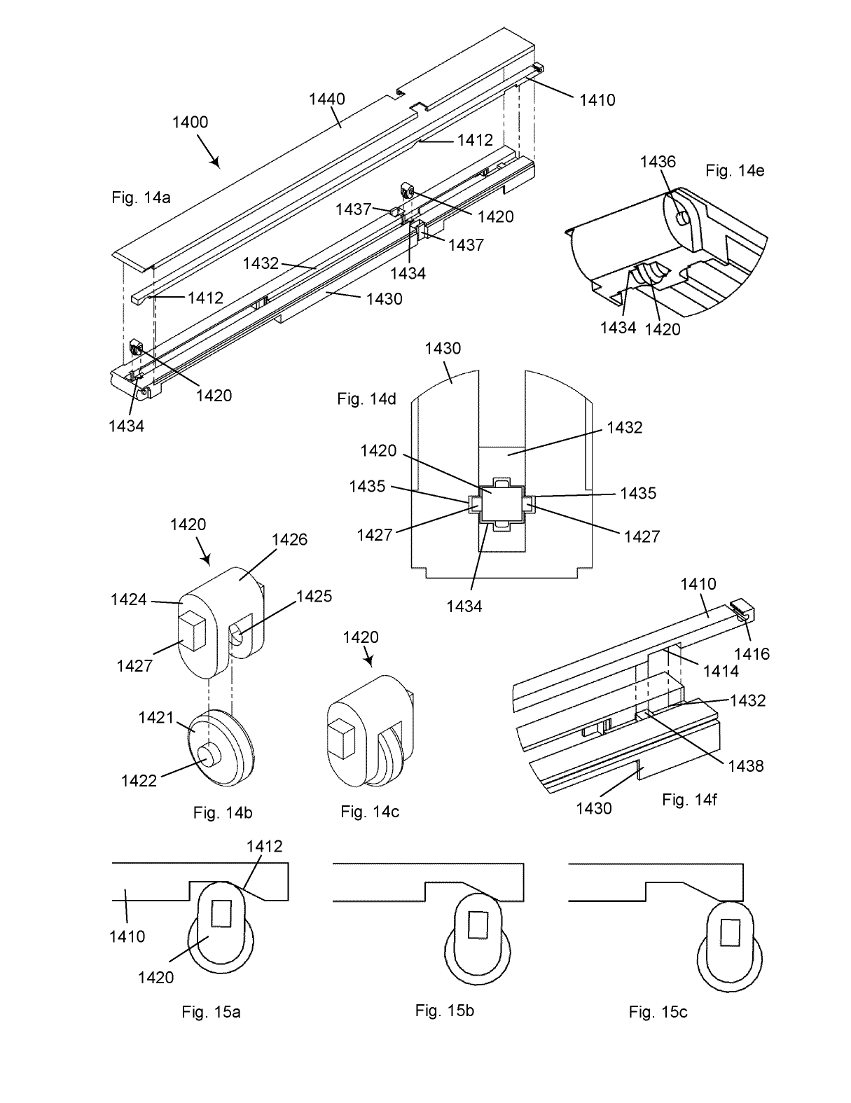

Now referring to FIGS. 14a to 14f, 15a to 15c and 16a to 16e, shown and described is a slide assembly for computer system apparatus which can be cooled by installation within a cooled enclosure in a data center environment. The slide assembly enabling computer system apparatus to be installed and removed from cooled enclosures without causing damage to attached thermal interface materials whilst reducing installation difficulty.

FIG. 14a shows an isometric view of an exploded slide assembly 1400, the slide assembly 1400 comprising force transfer rod 1410, wheel assemblies 1420, main body 1430 and lid 1440.

FIG. 14b shows an exploded view of a wheel assembly 1420 whilst FIG. 14c shows an assembled wheel assembly 1420. Wheel assembly 1420 comprises a wheel 1421 and body 1424, wheel 1421 has axles 1422 which are received by opening 1425 in the body 1424. Body 1424 further comprises a bearing surface 1426 and guides 1427.

Referring back to FIG. 14a, the main body 1430 comprises a channel 1432 which receives the force transfer rod 1410 and openings 1434 which receive the wheel assemblies 1420. FIG. 14d shows a partial top view of body 1430 showing the configuration of an opening 1434 and channel 1432, also shown is a wheel assembly 1420 in place within the opening 1434. The opening 1434 has guide slots 1435 into which the guides 1427 of the wheel assembly 1420 fit, the guide slots 1435 and the guides 1427 maintaining the wheel assembly 1420 in the correct orientation.

FIG. 14e shows the opening 1434 extending through the body 1430 allowing the wheel assembly 1420 to protrude through the bottom of the body 1430. The guide slots 1435 do not however extend all the way through the body 1430 and thus limit the movement of the wheel assembly 1420 and prevent the wheel assembly 1420 from passing through the body completely, this can also be seen in FIG. 14e. Whilst not shown an optional spring may be placed within the guide slot 1435, between the body 1430 and guide 1427 to counter gravity and maintain the wheel assembly 1420 within the body 1430 of the slide assembly 1400 when the force transfer rod 1410 is in the retracted position.

Body 1430 has a number of features which allow for attachment to the computer system chassis, these comprise: axles 1436, one of which is shown in FIG. 14e and has a counterpart axle 1436 on the opposing side of the body 1430, and; snap-fit hooks 1437, shown in FIG. 14a. The use of these features is discussed below.

FIG. 14f shows a partial perspective view of slide assembly 1400. The force transfer rod 1410 comprises a rod-stop feature 1414 which in combination with a corresponding stop feature 1438 in the channel 1432 of the body 1430 limits the movement of the force transfer rod 1410. Stop feature 1438 provides an ideal location where an optional contact switch or any position indicator mechanism may be placed to provide feedback on the position of the force transfer rod 1410. Also shown in FIG. 14f is a feature 1416 which allows for the attachment of a lever, the use of this feature 1416 is discussed below.

Referring back to FIG. 14a it can be seen that when the slide assembly 1400 is assembled the force transfer rod 1410 is contained by channel 1432 and lid 1440 and that the force transfer rod 1410 further comprises inclined plane features 1412 corresponding to each wheel assembly 1420. The wheel assemblies 1420 and force transfer rod 1410 are configured such that when the bearing surface 1426 of a wheel assembly 1420 is pressed against the force transfer rod 1410 a movement of the force transfer rod 1410 in a direction corresponding with its long axis enables the bearing surface 1426 of each wheel assembly 1420 to be moved along the inclined plane feature 1412 of the force transfer rod 1410. Thus retracting or deploying the wheel assembly 1420 depending on the position of the force transfer rod 1410.

FIGS. 15a, 15b and 15c show the interaction between the inclined plane features 1412 of the force transfer rod 1410 and wheel assemblies 1420. FIG. 15a shows the wheel assembly 1420 fully retracted, FIG. 15b shows the wheel assembly 1420 in a partially deployed position and FIG. 15c shows the wheel assembly 1420 in a fully deployed position.

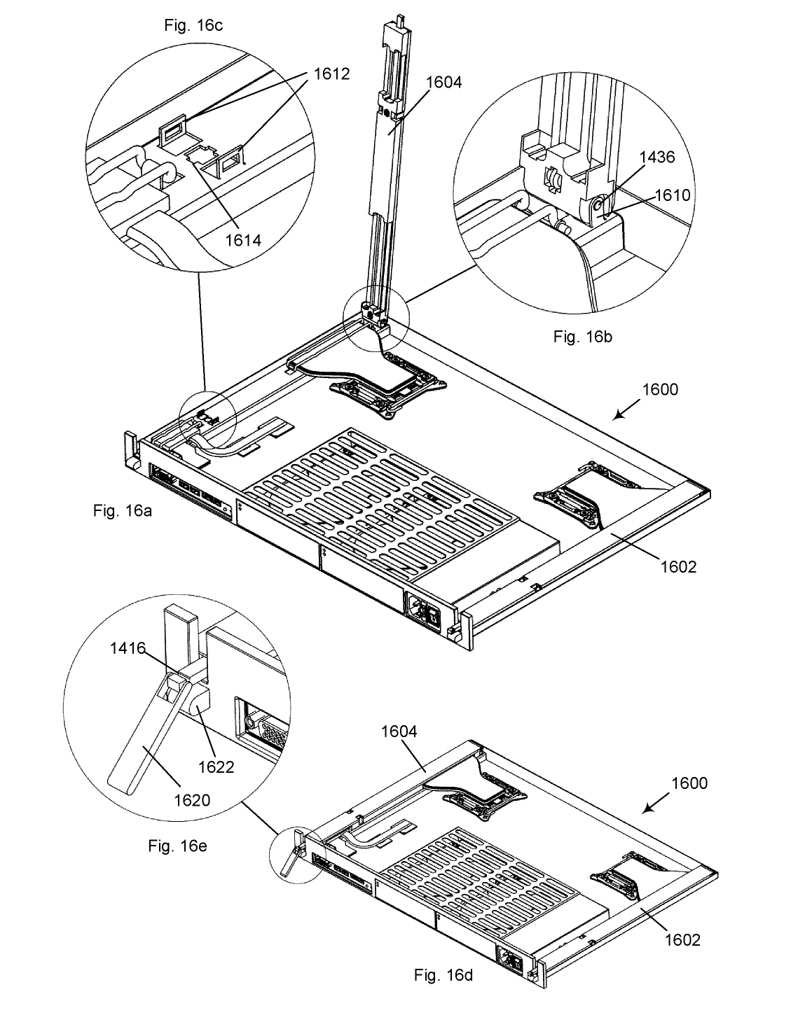

FIG. 16a shows a computer server 1600 with a slide assembly of the type shown in FIGS. 14 installed on each rail portion of the chassis. One slide assembly 1602 is shown in its operating position and the other slide assembly 1604 is shown rotated out of the way to allow access to other components installed on the rail portion of the chassis. It can be also be seen from FIG. 16a that the body of each slide assembly 1602 and 1604 has been configured to fit over each of the components installed on the rail portion of the chassis.

FIG. 16b provides a close up view of the computer server 1600 and illustrates chassis features 1610 which engage with the axles 1436 of the body of each slide assembly 1602 and 1604, the axles 1436 and chassis features 1610 allow each slide assembly 1602 and 1604 to be rotated out of the way to allow access to components installed on the rail portion of the chassis. They also provide structural support and bear the load of the rear wheel assembly when the wheels are deployed and the slide assemblies 1602 and 1604 are in their operating positions.

FIG. 16c provides a close up view of the computer server 1600 and illustrates chassis features 1612 which engage with the snap-fit hooks of the body of each slide assembly 1602 and 1604. The snap-fit hooks and corresponding features 1612 hold each slide assembly 1602 and 1604 in its operating position and bear the load of the front wheel assembly when the wheels are deployed. The snap-fit hooks and corresponding features 1612 also allow each slide assembly 1602 and 1604 to be quickly removed from its installed position by unhooking the snap-fit hooks.

Also shown in FIG. 16c is an aperture through which the wheel assemblies 1420 of the slide assembly 1602 and 1604 can protrude when the wheels are deployed and the slide assembly 1602 or 1604 is in operating position. The aperture 1614 being aligned with a wheel assembly when the slide assembly is in operating position.

FIG. 16d shows both slide assemblies 1602 and 1604 in their operating position, and FIG. 16e provides a close up view of the computer server 1600 illustrating a lever 1620 which may be used to deploy the wheels of the slide assembly 1604. The lever part 1620 engages with feature 1416 of the force transfer rod and, using a fulcrum feature 1622 on the front panel of the server 1600 the lever part 1620 can then be used to engender movement in the force transfer rod and deploy the wheel assemblies. The lever part 1620 could be attached permanently if so desired or can be attached only when needed. Understandably and as described below, any other type of mechanism engendering movement in the force transfer rod to deploy the wheel assemblies may be used.

The wheels of the slide assemblies 1602 and 1604 are retracted by pushing the force transfer rod 1410, with the rod suitably lubricated this may be operable without mechanical assistance such as lever 1620. However if the computer server 1600 is too heavy to allow this operation the lever 1620 and fulcrum feature 1622 can be modified to allow the lever to both deploy and retract the wheels.

The slide assembly embodiment described has been designed to use a small number of components and assembly operations as it is expected that slide assemblies such as these will be used only a couple of times during their operational lifetimes. Additional and alternative components may be used, including alternative force transfer means such as using a screw or worm drives or by introducing bearings to reduce energy losses when deploying or retracting the wheels. Another alternative is to replace the described wheel assemblies with a retractable low-friction bearing surface, such as a teflon coated foot, this may reduce the part count even further and may be adequate for some apparatus.

Although specific embodiments of the invention have been shown and described herein, it is to be understood that these embodiments are merely illustrative of the many possible specific arrangements that can be devised in application of the principles of the invention. Numerous and varied other arrangements can be devised by those of ordinary skill in the art without departing from the scope and spirit of the invention.

1. A computer system of the type which can be cooled by installing into a cooled enclosure, the cooled enclosure comprising a plurality of channels, the computer system comprising;
a rail configured to be received by a channel in the cooled enclosure;
a heat generating component, and;
a heat transmitting device, the heat transmitting device being in thermal contact with the heat generating component, the heat transmitting device being configured such that a portion of the heat transmitting device is contained within the channel of the enclosure when the computer system is installed in the enclosure.

2. The computer system of claim 1 wherein the heat transmitting device is a heatpipe.

3. The computer system of claim 1 wherein the heat transmitting device is a vapor chamber.

4. The computer system of any of claims 1 to 3 wherein the rail comprises an aperture and the heat transmitting device projects through the aperture.

5. A computer system chassis for a computer system of a type which can be cooled by installation into a cooled enclosure, the chassis comprising a rail adapted to be received by a channel in the enclosure when the chassis is installed in the enclosure, the rail being further configured such that when a heat transmitting device is installed in the chassis a portion of the heat transmitting device is contained within the channel of the enclosure when the chassis is installed in the enclosure.

6. The computer system chassis of claim 5, wherein the heat transmitting device is a heat pipe.

7. The computer system chassis of claim 5, wherein the heat transmitting device is a vapor chamber.

8. The computer system chassis of claim 5, wherein the chassis and rail are made of sheet metal.

9. The computer system chassis of claim 5, wherein the chassis and rail are fabricated from a single piece of sheet metal.

10. The computer system chassis of claim 5, wherein the rail further comprises an aperture, the aperture configured such that when the heat transmitting device is installed in the chassis and the chassis is installed in the enclosure, the heat transmitting device being adapted to be in contact with the enclosure through the aperture.

11. A computer system of a type which can be cooled by installation into a cooled enclosure, the computer system comprising:
the chassis of claim 5;
a heat generating component, and
a heat transmitting device in thermal contact with the heat generating component, the heat transmitting device being installed in the chassis in such a way that a portion of the heat transmitting device is contained within the channel of the enclosure when the chassis is installed in the enclosure.

12. The computer system of claim 11 wherein at least some of the portion of the heat transmitting device is also in thermal contact with a portion of the chassis which is to be in thermal contact with a cooled surface of the enclosure when the chassis is installed in the enclosure.

13. A computer system of a type which can be cooled by installation into a cooled enclosure within a data center, the computer system comprising:
the chassis of claim 10;
a heat generating component, and
a heat transmitting device in thermal contact with the heat generating component, the heat transmitting device being installed in the chassis in such a way that a portion of the heat transmitting device is contained within the channel of the enclosure and positioned such that it can contact a cooled surface of the enclosure through the aperture when the chassis is installed in the enclosure.

14. to 34. (canceled)
